(19) United States
(12) Patent Application Publication
(10) Pub. No.: US 2009/0285020 A1
(43) Pub. Date: Nov. 19, 2009

(54) METHOD OF PROGRAMMING A MULTI LEVEL CELL IN A NON-VOLATILE MEMORY DEVICE

(75) Inventors: Seong Je Park, Sacheon-si (KR); Seok Jin Joo, Seoul (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Icheon-si (KR)

(21) Appl. No.: 12/163,946

(22) Filed: Jun. 27, 2008

(30) Foreign Application Priority Data
May 14, 2008 (KR) 2008-44587

(51) Int. Cl. G11C 16/06

(52) U.S. Cl. 365/185.03; 365/185.22

(57) ABSTRACT

In a method of programming a multi level cell, program speed increases as a program operation/erase operation is repeatedly performed. Particularly, in an ISPP method of reducing a program start voltage, much time may be required to finish a first verifying operation in an initial step where a few program operations/erase operations are performed. Accordingly, a blind verifying method may be applied in accordance with the number of the program operation/erase operations.

### CROSS-REFERENCE TO RELATED APPLICATIONS

This application claims priority from Korean Patent Application No. 10-2008-0044587, filed on May 14, 2008, the contents of which are incorporated herein by reference in its entirety.

### BACKGROUND OF THE INVENTION

The present invention relates to a method of programming a multi level cell in a non-volatile memory device.

Recently, the demand has increased for a non-volatile memory device which electrically programs and erases data, and does not require a refresh function of periodically rewriting data.

A non-volatile memory device performs a program operation and an erase operation by changing a threshold voltage of a memory cell through moving of electrons by a high electric field applied to a thin oxide film.

When the program operation is performed on a specific memory cell, a verifying operation is performed to verify whether a threshold voltage of the programmed memory cell is more than a verifying reference voltage.

In a program operation of a single level cell, one verifying reference voltage is used because single level cells having two different states are included on one page.

However, in a program operation of a multi level cell, a plurality of verifying reference voltages are used because multi level cells having various states are included on one page. For example, when a most significant bit MSB is programmed in a program operation of a multi level cell having 2 bits, a verifying operation is performed on the basis of three verifying reference voltages.

When the program operation is performed using an incremental step pulse program ISPP method, three verifying operations are performed after a pulse is provided.

In a blind verifying method, some of the verifying operations are performed without simultaneously performing every verifying operation with reference to program speed of a memory cell.

However, since the program speed is increased when the number of the program operations/erase operations in the non-volatile memory device is augmented, a verifying operation is required due to the increase of program speed.

### SUMMARY OF THE INVENTION

It is a feature of the present invention to provide a method of programming a multi level cell in a non-volatile memory device. Program speed increases as a program operation/erase operation is repeatedly performed.

A method of programming a multi level cell in a non-volatile memory device of the present invention includes performing repeatedly a program operation and a first verifying operation until a memory cell is programmed to a voltage that is higher than a first verifying voltage of first verifying objection memory cells; performing repeatedly the program operation and the first verifying operation for a number of times equal to a first critical value when the memory cell is programmed to a voltage that is higher than the first verifying voltage; performing repeatedly the program operation, the first verifying operation and a second verifying operation for a number of times equal to a second critical value when the number of times that the program operation and the first verifying operation are performed is higher than the first critical value; and performing repeatedly the program operation, the first verifying operation, the second verifying operation and a third verifying operation when the number of times that the program operation, the first verifying operation and the second verifying operation are performed is higher than the second critical value.

A method of programming a multi level cell in a non-volatile memory device according to another example embodiment of the present invention includes performing repeatedly a program operation and a first verifying operation until a memory cell is programmed to a voltage that is higher than a first verifying voltage of first verifying objection memory cells; performing repeatedly the program operation and the first verifying operation for a number of times equal to a first critical value when the memory cell is programmed to a voltage that is higher than the first verifying voltage; performing repeatedly the program operation, the first verifying operation and a second verifying operation for a number of times equal to a second critical value when the program operation and the first verifying operation are performed for a number of times that is higher than the first critical value; and performing repeatedly the program operation, the first verifying operation, the second verifying operation and a third verifying operation when the number of times that the program operation, the first verifying operation and the second verifying operation are performed is higher than the second critical value. The first verifying operation is performed until every first verifying objection memory cell is programmed to a voltage that is higher than the first verifying voltage, the second verifying operation is performed until every second verifying objection memory cell is programmed to a voltage that is higher than the second verifying voltage, and the third verifying operation is performed until every third verifying objection memory cell is programmed to a voltage that is higher than the third verifying voltage.

As described above, in a method of programming a multi level cell of the present invention, program speed increases as a program operation/erase operation is repeatedly performed. Particularly, in an ISPP method of reducing a program start voltage, much time may be required to finish a first verifying operation in an initial step where a few program operations/erase operations are performed. Accordingly, a blind verifying method may be applied in accordance with the number of the program operation/erase operations.

### BRIEF DESCRIPTION OF THE DRAWINGS

The above and other features and advantages of the present invention will become readily apparent by reference to the following detailed description when considered in conjunction with the accompanying drawings wherein:

FIG. 1 is a view illustrating a method of programming a multi level cell in a non-volatile memory device;

FIG. 2 is a view illustrating a program/verifying method for an MSB program operation in the non-volatile memory device;

FIG. 3 is a view illustrating a program/verifying method in a non-volatile memory device according to one example embodiment of the present invention;

FIG. 4 is a flow chart illustrating a verifying operation in a non-volatile memory device according to one example embodiment of the present invention;

FIG. 5 is a flow chart illustrating a verifying operation in the non-volatile memory device according to another example embodiment of the present invention; and

FIG. 6 is a view illustrating a program/erase method in the non-volatile memory device according to another example embodiment of the present invention.

### DESCRIPTION OF SPECIFIC EMBODIMENTS

Hereinafter, the preferred embodiments of the present invention will be explained in more detail with reference to the accompanying drawings.

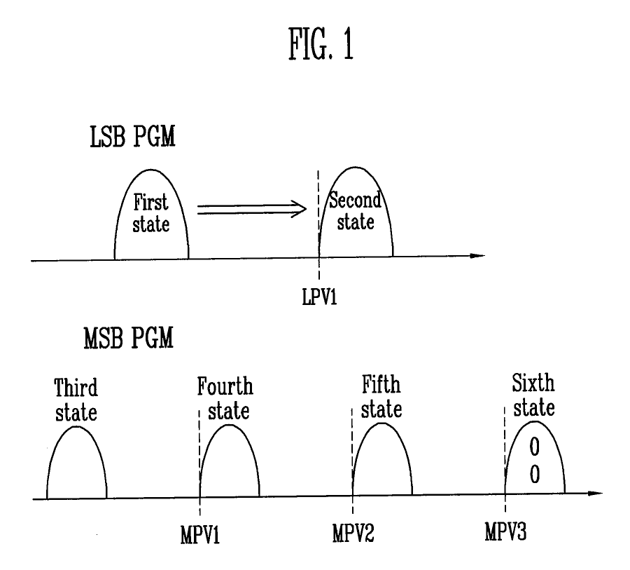

FIG. 1 is a view illustrating a method of programming a multi level cell in a non-volatile memory device.

Two different threshold voltage distributions are provided when a least significant bit LSB is programmed. It is assumed that a threshold voltage distribution of a memory cell programmed to a voltage that is higher than a verifying voltage LPVL has a second state, and a threshold voltage distribution of a memory cell programmed to a voltage that is smaller than the verifying voltage LPVL has a first state.

Subsequently, a most significant bit MSB is programmed when the LSB is programmed. As a result, four different threshold voltage distributions, i.e. a third state to a sixth state, are provided in accordance with programming the MSB. Verifying voltages depend on the threshold voltage distributions, e.g. a first verifying voltage MPV1, a second verifying voltage MPV2 and a third verifying voltage MPV3 having sequential magnitude.

It is assumed that a threshold voltage distribution of a memory cell programmed to a voltage that is higher than the third verifying voltage MPV3 has the sixth state, and a threshold voltage distribution of a memory cell programmed to a voltage that is less than the third verifying voltage MPV3 and higher than the second verifying voltage MPV2 has a fifth state. In addition, it is assumed that a threshold voltage distribution of a memory cell programmed to a voltage that is less than the second verifying voltage MPV2 and higher than the first verifying voltage MPV1 has a fourth state, and a threshold voltage distribution of a memory cell programmed to a voltage that is less than the first verifying voltage MPV1 has the third state.

Moreover, memory cells to be programmed to the fourth state, memory cells to be programmed to be the fifth state and memory cells to be programmed to the sixth state are referred to as first verifying objection memory cells, second verifying objection memory cells and third verifying objection memory cells, respectively.

The number of the verifying voltages for verifying the programming of the MSB is higher than that of the verifying voltages for verifying the programming of the LSB.

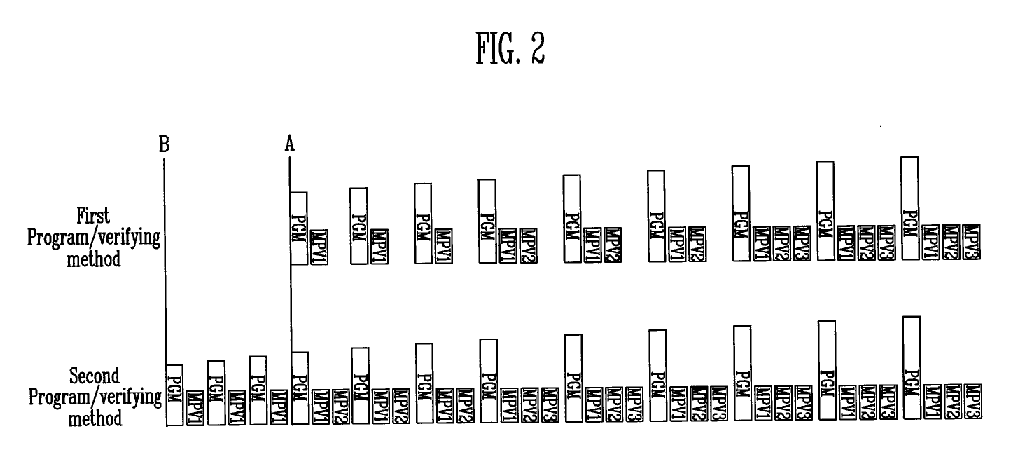

FIG. 2 is a view illustrating a program/verifying method for an MSB program operation in the non-volatile memory device.

In a first program/verifying method, a verifying operation is performed on the basis of the first verifying voltage MPV1 after a program voltage is applied to a corresponding word line.

Generally, a verifying operation should also be performed on the basis of the second verifying voltage MPV2, the third verifying voltage MPV3, etc. However, since the possibility that a memory cell is programmed to a voltage more than the second verifying voltage MPV2 is very low, the verifying operation is performed on the basis of only the first verifying voltage MPV1. This verifying method is referred to as a blind verifying method.

A verifying operation is performed on the basis of the second verifying voltage MPV2 and the first verifying voltage MPV1 after applying the program voltage and the verifying operation approximately three times based on the first verifying voltage MPV1.

A verifying operation is performed on the basis of the third verifying voltage MPV3 after performing the verifying operation approximately three times based on the verifying voltages MPV1 and MPV2.

The number of the verifying operations performed based on only the first verifying voltage MPV1 and the number of the verifying operations performed based on only the verifying voltages MPV1 and MPV2 are preset.

Hereinafter, a second program/verifying method will be described in detail.

The second program/verifying method provides a program start pulse having a magnitude smaller than that in the first program/verifying method shown in FIG. 2 to compensate for program speed that has increased as the program operation/erase operation is repeatedly performed.

Since the program speed is rapid when many program operations/erase operations are performed, a threshold voltage of a corresponding memory cell is changed even though the program pulse is provided with a small magnitude. Accordingly, a verifying operation is performed even though the program pulse having a small magnitude is provided. In addition, the verifying operation based on the verifying voltages MPV1 and MPV2 is performed after which the threshold voltage is increased, i.e. A time point.

However, since the program speed is slow when a few of the program operations/erase operations are performed, the threshold voltage of the memory cell is changed slightly when the program pulse having a small magnitude is provided. Accordingly, a verifying operation may not be performed when the program pulse is provided with a small magnitude. Additionally, since an increased width of the threshold voltage is small, the verifying operation based on the first verifying voltage MPV1 is performed after the program pulse is applied, i.e. A time point, but the verifying operation based on the second verifying voltage MPV2 may not be performed.

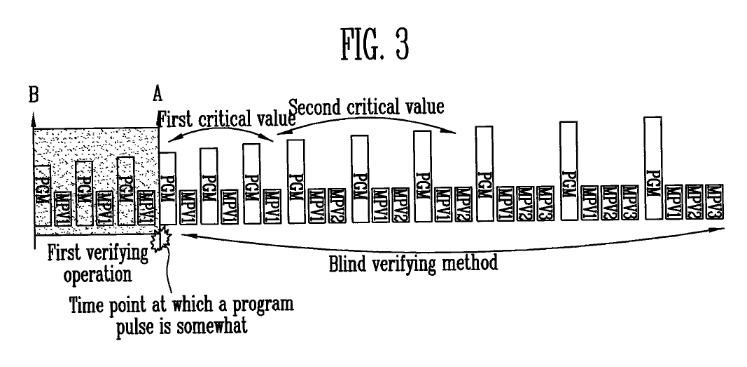

FIG. 3 is a view illustrating a program/verifying method in a non-volatile memory device according to one example embodiment of the present invention.

The program/verifying method of the present embodiment provides a program start voltage having a small magnitude, and program speed increases as the number of program operation/erase operations is augmented.

When the above blind verifying method is applied to the program/verifying method under the above conditions, a verifying operation based on a second verifying voltage MPV2 and a verifying operation based on a first verifying voltage MPV1 may be unnecessarily performed in an initial step where a limited number of program operation/erase operations are performed.

To prevent the above phenomenon, the program/verifying method of the present embodiment uses the blind verifying method only when a memory cell is programmed to a voltage that is higher than the first verifying voltage MPV1.

The first verifying operation based on the first verifying voltage MPV1 and a program operation through an ISPP method are performed in turn until a memory cell is programmed to a voltage that is higher than the first verifying voltage MPV1 as shown in FIG. 3. In addition, the blind verifying method is performed after the memory cell is programmed to a voltage that is higher than the first verifying voltage MPV1.

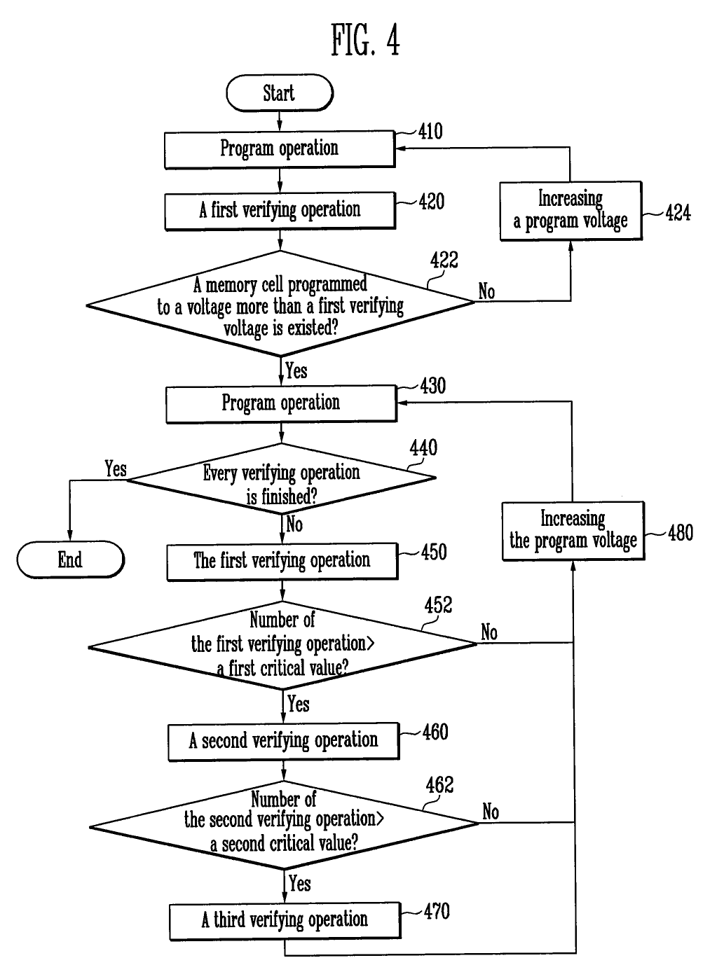

FIG. 4 is a flow chart illustrating a verifying operation in a non-volatile memory device according to one example embodiment of the present invention.

In step S410, a program operation is performed using a program start voltage. The program start voltage is smaller than that applied in a common program operation. In other words, the preset program start voltage having a small magnitude is applied and program speed increases as the program operation/erase operation is repeatedly performed.

In step S420, a first verifying operation is performed to verify whether a first verifying objection memory cell is programmed to a voltage more than the first verifying voltage MPV1. The first verifying objection memory cell refers to a memory cell to be programmed to a voltage smaller than the second verifying voltage MPV2 and more than the first verifying voltage MPV1, i.e. the fourth state as mentioned above in FIG. 1.

In step S422, it is detected through the first verifying operation whether a memory cell is programmed to a voltage more than the first verifying voltage MPV1. The detection process will be described with reference to a verifying operation for a page buffer of a common non-volatile memory device.

When a specific memory cell is programmed to a voltage more than the first verifying voltage MPV1, the memory cell is turned on, and a current path of a cell string having the memory cell is blocked. Accordingly, a voltage level of a bit line precharged to a high level is maintained and is provided to a sensing node. As a result, the sensing node has a high voltage level, and data stored in a register is converted.

When at least one memory cell, of which data is converted, is found in a whole page buffer, the memory cell is assumed to be a memory cell programmed to a voltage more than the first verifying voltage MPV1.

In step S422 a determination is made whether the blind verifying method will be performed. Particularly, the blind verifying method is performed when a memory cell is programmed to a voltage more than the first verifying voltage MPV1 in step S424. However, when a memory cell is programmed to a voltage that is less than the first verifying voltage MPV1, the program voltage is increased by a step voltage in step S424, and then the steps S410 and S420 are again performed.

In step S430, when a memory cell programmed to a voltage more than the first verifying voltage MPV1 is detected through the first verifying operation, the program voltage applied in a preceding program operation is augmented by the step voltage, and then a program operation is performed by using the augmented program voltage.

In step S440, a determination is made whether every verifying operation is finished. It is verified through the first verifying operation to the third verifying operation whether every verifying objection memory cell is programmed.

In a non-volatile memory device, a pass signal or a fail signal is generated after each of the verifying operations is performed. The pass signal includes information that every memory cell is programmed to a voltage that is higher than a corresponding verifying voltage through data stored in each register in a page buffer. In addition, the fail signal has information that every memory cell is not programmed to a voltage that is higher than the verifying voltage.

It is verified through the above pass signal/fail signal whether the first verifying operation to the third verifying operation are finished.

When the first verifying operation to the third verifying operation are finished, the program operation is terminated because each of the verifying objection memory cells is programmed to a voltage that is higher than a corresponding verifying voltage.

In another example embodiment of the present invention, the number of the program operations may be limited to a set number. When the verifying operation is not finished after the set number of program operations is performed, it is determined that a corresponding memory cell has failed, and a bad block processing operation is performed.

Subsequently, when a determination is made that the verifying operation is not finished, the first verifying operation, the second verifying operation and the third verifying operation are performed in sequence.

Particularly, in steps S450, S452, S480 and S430, only the first verifying operation is performed for a number of times equal to a first critical value. In this blind verifying method, only the first verifying operation is performed for a number of times equal the first critical value in an initial step where a small program voltage is applied. A determination is made whether the number of first verifying operations performed is higher than the first critical value after the first verifying operation is performed in step S452.

When the number of first verifying operations performed is less than or equal to the first critical value, the program voltage is increased by a step voltage, and the program operation in step S430 is performed again using the increased program voltage. The program operation and the first verifying operation are repeatedly performed for a number of times equal to the first critical value. The first critical value is selected as an optimized value by a user in accordance with characteristics of a corresponding memory cell.

It is verified whether the memory cell has passed or failed in accordance with data stored in the register of the page buffer while the first verifying operation is performed. The verified result is used in step S440.

In step S460, when the first verifying operation is performed for a number of times equal to the first critical value, a second verifying operation is performed to verify whether the second verifying objection memory cell is programmed to a voltage that is higher than the second verifying voltage MPV2 after the program operation and the first verifying operation are performed.

In steps S460, S462, S480 and S430, the first verifying operation and the second verifying operation are performed for a number of times equal to a second critical value through the blind verifying method.

Particularly, in the step S462, a determination is made whether the number of times that the second verifying operation is performed is higher than the second critical value after the second verifying operation is performed.

When the number of times that the second verifying operation is performed is less than or equal to the second critical value, the program voltage is increased by the step voltage, and the program operation in the step S430 is performed again using the increased program voltage. The program operation, the first verifying operation and the second verifying operation are repeatedly performed for a number of times equal to the second critical value as shown in FIG. 3. The second critical value is selected as an optimized value by a user in accordance with characteristics of a corresponding memory cell.

It is verified whether the memory cell has passed or failed in accordance with data stored in the register of the page buffer while the second verifying operation is performed. The verified result is used in step S440.

In step S470, when the second verifying operation is performed for a number of times equal to the second critical value, a third verifying operation is performed to verify whether the third verifying objection memory cell is programmed to a voltage that is higher than the third verifying voltage MPV3 after the program operation, the first verifying operation and the second verifying operation are performed.

It is verified whether the memory cell has passed or failed in accordance with data stored in the register of the page buffer while the third verifying operation is performed. The verified result is used in step S440.

Since the blind verifying method is not used in the third verifying operation, it is not determined whether the number of times that the third verifying operation is performed is higher than the third critical value. In addition, the program voltage is increased by the step voltage after the third verifying operation is performed in step S480, and the program operation is performed again using the increased program voltage in step S430.

In one example embodiment of the present invention, a step of determining whether a number of times that the third verifying operation is performed is higher than a given critical value may be further performed. When the number of times that the third verifying operation is performed is higher than the given critical value, the bad block processing operation may be performed on a corresponding memory cell.

Every verifying operation, i.e. the first verifying operation to the third verifying operation, is not performed after one program operation is performed, but is performed through the blind verifying method.

The program start voltage is set to have a small magnitude considering the number of the program operation/erase operations. Hence, the blind verifying method is used from a time point at which a memory cell is programmed to a voltage that is higher than the first verifying voltage MPV1.

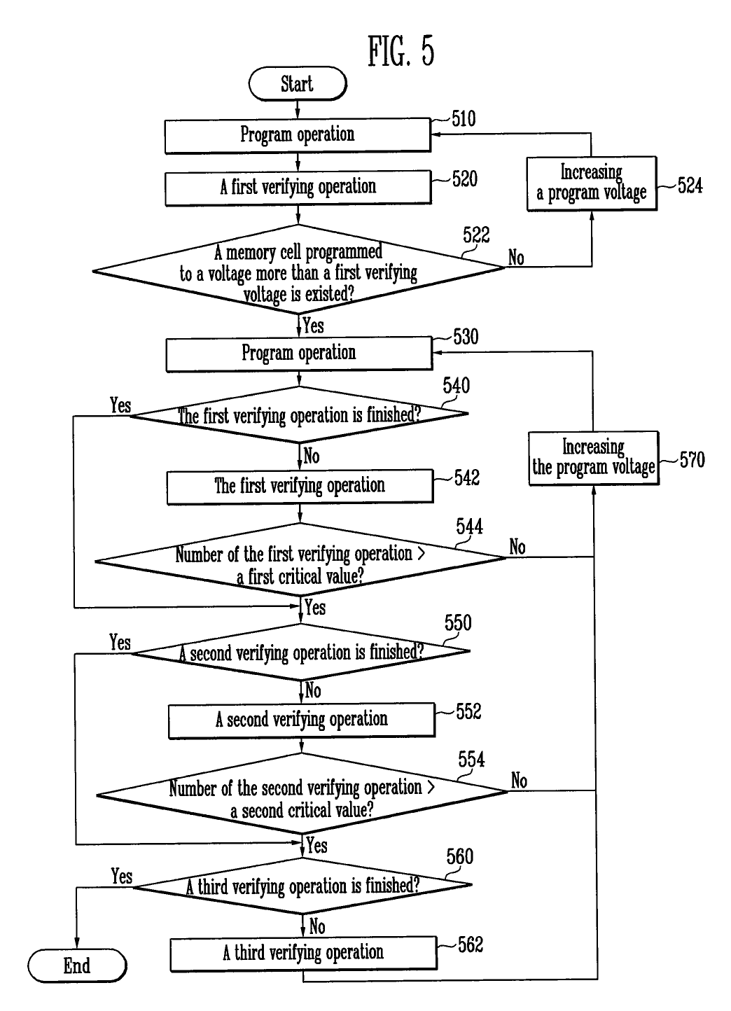

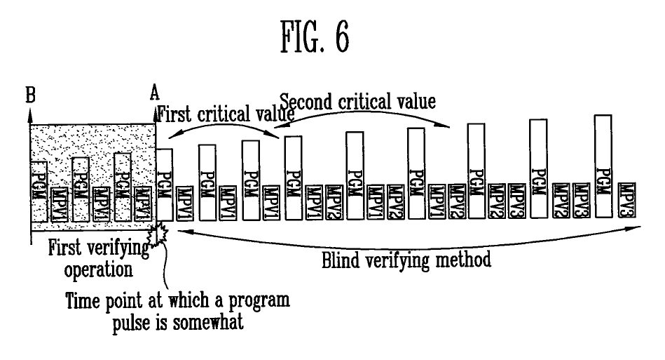

FIG. 5 is a flow chart illustrating a verifying operation in the non-volatile memory device according to another example embodiment of the present invention. FIG. 6 is a view illustrating a program/verifying method in the non-volatile memory device according to another example embodiment of the present invention.

The program/verifying method of the present embodiment is similar to that in FIG. 4. However, in the program/verifying method of the present embodiment, when a specific verifying operation is finished while the first verifying operation to the third verifying operation are performed, the specific verifying operation is no longer performed. In other words, when every first verifying objection memory cell is programmed to a voltage that is higher than the first verifying voltage MPV1 while the verifying operations are performed as shown in FIG. 6, i.e. the first verifying operation is finished, the first verifying operation is no longer performed, but the other verifying operations are performed.

In short, the program/verifying method of the present embodiment is similar to that in FIG. 4, and further includes a step of determining whether each verifying operation is finished before the verifying operations are performed.

In other words, in step S540, it is verified whether the first verifying operation is finished in a preceding program operation before performing the first verifying operation.

It is detected whether a corresponding memory cell has passed/failed through data stored in the register of the page buffer while the first verifying operation is performed in a preceding program operation. Then, it is verified through the detection result whether the first verifying operation is finished.

In step S550, it is verified whether the second verifying operation is finished when the first verifying operation is finished. However, when the first verifying operation is not finished, the first verifying operation is performed in step S542. The first verifying operation is performed a number of times equal to the first critical value in steps S542, S544, S570 and S530. This operation corresponds to the blind verifying method, and is similar to that in FIG. 4.

Particularly, it is determined whether the number of times that the first verifying operation is performed is higher than the first critical value after the first verifying operation is performed in step S544.

When it is determined that the number of times that the first verifying operation is performed is less than or equal to the first critical value, a corresponding program voltage is increased by a step voltage, and the program operation is performed again using the increased program voltage.

The program operation and the first verifying operation are repeatedly performed a number of times equal to the first critical value as shown in FIG. 6. The first critical value is selected as an optimized value by a user in accordance with characteristics of a corresponding memory cell.

It is verified whether the memory cell has passed or failed in accordance with data stored in the register of the page buffer while the first verifying operation is performed. The verified result is used in step S540.

In step S550, when the first verifying operation is performed a number of times equal the first critical value, or when the first verifying operation is finished, it is verified whether the second verifying operation is finished in a preceding program operation before performing the second verifying operation in step S550.

It is detected whether a corresponding memory cell has passed/failed through data stored in the register of the page buffer while the second verifying operation is performed in a preceding program operation. Then, it is verified through the detection result whether the second verifying operation is finished.

The second verifying operation is performed a number of times equal to the second critical value through the blind verifying method in steps S552, S554, S570 and S530.

Particularly, it is determined whether a number of times that the second verifying operation is performed is higher than the second critical value after the second verifying operation is performed in step S554.

When it is determined that the number of times that the second verifying operation is performed is less than or equal to the second critical value, a corresponding program voltage is increased by the step voltage, and the program operation is performed again using the increased program voltage.

In other words, the program operation, the first verifying operation and the second verifying operation are repeatedly performed for a number of times equal to the second critical value as shown in FIG. 6. The second critical value is selected as an optimized value by a user in accordance with characteristics of a corresponding memory cell.

It is detected whether or not a corresponding memory cell has passed/failed through data stored in the register of the page buffer while the second verifying operation is performed. The detection result is used in step S550.

In step S560, when the second verifying operation is performed a number of times equal to the second critical value, or when the second verifying operation is finished, it is verified whether the third verifying operation is finished in a preceding program operation before performing the third verifying operation.

It is detected whether a corresponding memory cell has passed/failed through data stored in the register of the page buffer while the third verifying operation is performed in a preceding program operation. Then, it is verified through the detection result whether the third verifying operation is finished.

When the third verifying operation is finished, the program operation is terminated. Since the third verifying voltage MPV3 is usually highest, the first verifying operation and the second verifying operation are finished before the third verifying operation is finished. Accordingly, when the third verifying operation is finished, the program operation is terminated.

Since the blind verifying method is not used in the third verifying operation, it is not determined whether the number of times that the third verifying operation is performed is higher than the third critical value. In addition, the program voltage is increased by the step voltage after the third verifying operation is performed in the step S570, and the program operation is performed again using the increased program voltage in step S530. Repeating the program operation depends on whether the third verifying operation is finished. It is detected whether the memory cell has passed/failed through data stored in the register of the page buffer while the third verifying operation is performed. Then, it is verified through the detection result whether the third verifying operation is finished after the program operation is finished in step S560.

In one example embodiment of the present invention, a step of determining whether the number of times that the third verifying operation is performed is higher than a given critical value may be further performed. When the number of times that the third verifying operation is performed is higher than the given critical value, the bad block processing operation may be performed on a corresponding memory cell.

In brief, every verifying operation, i.e. the first verifying operation to the third verifying operation, is not performed after one program operation is performed, but is performed through the blind verifying method.

The program start voltage is set to have a small magnitude considering the number of program operation/erase operations. Accordingly, the blind verifying method is applied to the verifying operation from a time point at which a memory cell is programmed to a voltage that is higher than the first verifying voltage. Additionally, when a specific verifying operation is performed, the verifying operation may not be performed in a next program operation.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to affect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method of programming a multi level cell in a non-volatile memory device, wherein the multi level cell comprises a first verifying objection memory cell, a second verifying objection memory cell and a third verifying objection memory cell, the method comprising:
performing repeatedly a program operation and a first verifying operation until the first verifying objection memory cell is programmed to a voltage that is higher than a first verifying voltage;
performing repeatedly the program operation and the first verifying operation for a number of times equal to a first critical value in the event that the first verifying objection memory cell is programmed to the voltage that is higher than the first verifying voltage;
performing repeatedly the program operation, the first verifying operation and a second verifying operation on the second verifying objection memory cell for a number of times equal to a second critical value in the event that the number of times that the program operation and the first verifying operation is performed is higher than the first critical value; and
performing repeatedly the program operation, the first verifying operation, the second verifying operation and a third verifying operation on the third verifying objection memory cell in the event that the number of times that the program operation, the first verifying operation and the second verifying operation is performed is higher than the second critical value.

2. The method of claim 1, further comprising:
terminating the program operation in the event that every verifying objection memory cell is programmed to a voltage that is higher than a corresponding verifying voltage through the first verifying operation, the second verifying operation and the third verifying operation.

3. The method of claim 1, wherein the steps of performing each include increasing a corresponding program voltage by a step voltage.

4. A method of programming a multi level cell in a non-volatile memory device, wherein the multi level cell comprises a plurality of verifying objection memory cells, the method comprising:
performing repeatedly a program operation and a first verifying operation until a first verifying objection memory cell is programmed to a voltage that is higher than a first verifying voltage;
performing repeatedly the program operation and the first verifying operation on the first verifying objection memory cell for a number of times that is equal to a first critical value in the event that the first verifying objection memory cell is programmed to a voltage that is higher than the first verifying voltage;
performing repeatedly the program operation, the first verifying operation and a second verifying operation on a second verifying objection memory cell for a number of times equal to a second critical value in the event that the number of times that the program operation and the first verifying operation is performed is higher than the first critical value; and
performing repeatedly the program operation, the first verifying operation, the second verifying operation and a third verifying operation on a third verifying operation memory cell in the event that the number of times that the program operation, the first verifying operation and the second verifying operation is performed is higher than the second critical value,
wherein the first verifying operation is performed until the first verifying objection memory cell is programmed to a voltage that is higher than the first verifying voltage, the second verifying operation is performed until the second verifying objection memory cell is programmed to a voltage that is higher than the second verifying voltage, and the third verifying operation is performed until the third verifying objection memory cell is programmed to a voltage that is higher than the third verifying voltage.

5. The method of claim 4, further comprising:
terminating the program operation in the event that every verifying objection memory cell is programmed to a voltage that is higher than a corresponding verifying voltage through the first verifying operation, the second verifying operation and the third verifying operation.

6. The method of claim 4, wherein the steps of performing each include increasing a corresponding program voltage by a step voltage.

7. A method of programming a multi level cell in a non-volatile memory device, wherein the multi level cell comprises a plurality of first verifying objection memory cells, a plurality of second verifying objection memory cells and a plurality of third verifying objection memory cells, the method comprising:
performing repeatedly a program operation and a first verifying operation on the first verifying objection memory cells, wherein the first verifying operation is performed until every first verifying objection memory cell is programmed to a voltage that is higher than a first verifying voltage
performing repeatedly the program operation, the first verifying operation and a second verifying operation on the second verifying memory cells, wherein the second verifying operation is performed until every second verifying objection memory cell is programmed to a voltage that is higher than a second verifying voltage; and
performing repeatedly the program operation, the first verifying operation, the second verifying operation and a third verifying operation on the third verifying objection memory cells until every third verifying objection memory cell is programmed to a voltage that is higher than a third verifying voltage.

8. The method of claim 7, further comprising:
terminating the program operation in the event that every verifying objection memory cell is programmed to a voltage that is higher than the corresponding verifying voltage through the first verifying operation, the second verifying operation and the third verifying operation.

9. The method of claim 7, wherein the steps of performing each include increasing the corresponding program voltage by a step voltage.

10. The method of claim 7, wherein performing repeatedly the program operation and the first verifying operation comprises performing repeatedly the program operation and the first verifying operation on the first verifying objection memory cells for a number of times equal to a first critical value in the event that every first verifying objection memory cell is programmed to the voltage that is higher than the first verifying voltage.

11. The method of claim 10, wherein performing repeatedly the program operation, the first verifying operation and the second verifying operation comprises performing repeatedly the program operation, the first verifying operation and the second verifying operation on the second verifying objection memory cells for a number of times equal to a second critical value in the event that the number of times that the program operation and the first verifying operation is performed is higher than the first critical value.

12. The method of claim 11, wherein performing repeatedly the program operation, the first verifying operation, the second verifying operation and the third verifying operation comprises performing repeatedly the program operation, the first verifying operation, the second verifying operation and the third verifying operation on the third verifying objection memory cells in the event that the number of times that the program operation, the first verifying operation and the second verifying operation is performed is higher than the second critical value.
